(19) United States
(12) Patent Application Publication
(10) Pub. No.: US 2024/0227574 A1
(43) Pub. Date: Jul. 11, 2024

(54) Solar Charging Device for Electric Vehicles

(71) Applicant: Ernest Howard, Plainfield, NJ (US)

(72) Inventor: Ernest Howard, Plainfield, NJ (US)

(21) Appl. No.: 18/397,359

(22) Filed: Dec. 27, 2023

Related U.S. Application Data
(60) Provisional application No. 63/437,383, filed on Jan. 6, 2023.

(51) Int. Cl. B60L 8/00; B60L 53/62; B60L 58/12; H02S 40/20

(52) U.S. Cl. CPC B60L 8/003; B60L 53/62; B60L 58/12; H02S 40/20

(57) ABSTRACT

The present invention is a solar charging system for electric vehicles. The system comprising a vehicle roof having multiple layers, with a transparent, toughened glass top or outer layer for protection and visibility. A middle layer integrating solar panels for absorbing solar energy and converting same into electric power. A bottom or inner layer is tinted or transparent. In some embodiments, a charging controller monitors and optimizes the battery charging process. Solar irradiance sensors measure real-time sunlight intensity, enabling automatic disconnection when sunlight falls below a certain threshold. The system can be integrated into new electric vehicles or retrofitted as an aftermarket product. The system recharges the battery pack of the EV and eliminates planning trips around charging/gas stations equipped with electric vehicle charging stations for recharging the battery. Our goal is to present a charging system that is activated when battery level is equal to or less than 80%.

### CROSS-REFERENCE TO RELATED APPLICATION

The present application claims priority to, and the benefit of, U.S. Provisional Application No. 63/437,383, which was filed on Jan. 6, 2023, and is incorporated herein by reference in its entirety.

### FIELD OF THE INVENTION

The present invention generally relates to the field of solar charging of electric vehicles. More specifically, the present invention relates to a novel solar charging system designed to be installed on the roof of electric vehicles (EVs). The system includes a top glass layer, a middle glass layer including embedded solar panels, and a bottom glass layer. The system can be integrated or retrofitted to an EV. The solar panels provide electric power to recharge the battery pack of the vehicle to increase the range of the EV without requiring frequent charging stops. Accordingly, the present disclosure makes specific reference thereto. Nonetheless, it is to be appreciated that aspects of the present invention are also equally applicable to other like applications, devices, and methods of manufacture.

### BACKGROUND

By way of background, electric vehicles (EVs) have become popular as they are eco-friendly, significantly reducing or even eliminating emissions of pollutants and greenhouse gases. By using electricity as a power source, EVs contribute to lower air pollution levels and reduced carbon emissions, helping to mitigate the environmental impact of transportation. EVs also reduce the world's reliance on gasoline and fossil fuels.

EVs also have lower operating costs compared to traditional vehicles powered by internal combustion engines. Charging an EV is often more economical than filling up a gas tank, and typically have fewer maintenance and repair expenses.

However, in addition to the above mentioned advantages, inconvenience associated with charging EVs, can discourage potential buyers. Battery packs of EVs have limited power levels which can run the EV for a limited range. Availability of charging infrastructure can be a significant hurdle. Many areas, especially along major roadways, may lack sufficient EV charging stations, making long-distance travel in an EV more challenging. As a result, EV owners are concerned about running out of battery power at inconvenient times, potentially leaving them stranded. Ongoing efforts to overcome the problems are increasing power storage capacity of the battery pack, however, it comes with increased battery size and cost. Individuals desire an alternative way for charging their electric vehicle battery to overcome charging problems associated with electric vehicles.

Therefore, there exists a long felt need in the art for an alternative system for charging batteries of an electric vehicle. Additionally, there is a long felt need in the art for an electric vehicle that enables vehicle passengers to travel longer amounts of time and distances without requiring frequent charges. Moreover, there is a long felt need in the art for a novel solar charging system for EV owners that can be affixed directly to the roof area of the vehicle. Further, there is a long felt need in the art for an EV solar charging system that can be installed on a roof of a vehicle to recharge vehicular batteries to prevent users from running out of battery power. Furthermore, there is a long felt need in the art for a solar charging system that is durable and that makes it easier for individuals to buy electric vehicles by reducing charging problems of electric vehicles. Finally, there is a long felt need in the art for a solar charging system and method for electric vehicles that reduce frequent charging requirements of the EVs and reliance on charging stations.

The subject matter disclosed and claimed herein, in one embodiment thereof, comprises an electric vehicle (EV) with solar panels for charging a built-in vehicular battery. The EV has a panoramic roof, the roof extends between the front end and the rear end of the EV's top surface or outer layer. The panoramic roof is transparent or semi-transparent to provide occupants with an unobstructed view of their surroundings and to enable natural light to penetrate the vehicle interior. A plurality of solar panels is integrated into the panoramic roof and positioned to cover approximately 80% of the area of the roof's surface. A clear toughened glass layer covers the solar panels for protection against environmental elements and physical damage. The solar panels are fabricated from thin-film solar cells or solar glass, permitting the transmission of natural light through the panels while efficiently capturing and converting solar energy into electric power for recharging the EV's battery pack, thereby the EV travels further distances without having to stop at a charging station. The solar panels can be installed in a multilayered structure which has three glass layers in which the middle layer includes the solar panels.

In this manner, the solar charging device and equipped vehicle of the present invention accomplish all of the forgoing objectives and provide vehicle owners with solar panels affixed directly to the roof area of the vehicle. The use of solar panels enables vehicular battery to be recharged using electric power provided by the solar panels while the vehicle is in operation and also while the vehicle is parked outside. The EV prevents the battery from running out of power while on the road and eliminates the need to plan trips around gas stations equipped with electric vehicle charging stations for recharging the battery.

### SUMMARY OF THE INVENTION

The following presents a simplified summary in order to provide a basic understanding of some aspects of the disclosed innovation. This summary is not an extensive overview, and it is not intended to identify key/critical elements or to delineate the scope thereof. Its sole purpose is to present some general concepts in a simplified form as a prelude to the more detailed description that is presented later.

The subject matter disclosed and claimed herein, in one embodiment thereof, comprises an electric vehicle (EV) with integrated solar panels for charging a built-in vehicular battery. The EV comprising a panoramic roof, the roof extends between a front end and a rear end of the EV's top surface or outer layer. The panoramic roof is transparent or semi-transparent to provide occupants with an unobstructed view of their surroundings and to enable natural light to penetrate the vehicle interior. A plurality of solar panels is integrated into the panoramic roof and positioned to cover approximately 90% of the length and 90% of the width of the roof's surface. A clear toughened glass layer covers the solar panels for protection against environmental elements and physical damage. The solar panels are fabricated from thin-film solar cells or solar glass, permitting the transmission of natural light through the panels while efficiently capturing and converting solar energy into electric power for recharging the EV's battery pack.

In a further embodiment of the present invention, a multi-layered solar charging vehicle roof device for installation on the roof of an electric vehicle is disclosed. The device includes a top or outer layer constructed from transparent and toughened glass. The top or outer layer provides both visibility and protection against environmental elements, including rain, wind, and debris. A middle layer which includes a plurality of integrated solar panels. Each solar panel is designed to absorb solar energy and convert it into electric power. A bottom or inner layer constructed from either transparent or tinted glass. The bottom or inner layer serves as an additional protective barrier and an insulation layer for the interior of the electric vehicle. The device is designed to adapt to the design and structure of various electric vehicles, whether integrated during the manufacturing process of an electric vehicle, or as a retrofit aftermarket product, enhancing the vehicle's energy efficiency.

In yet another embodiment, the top or outer layer having a thickness from 1 mm to 4 mm, and the middle layer having a thickness ranging from about 3 mm to about 8 mm, providing structural support and insulation for the vehicle's interior.

In yet another embodiment, a solar panel system for electric vehicles to recharge vehicle battery pack is disclosed. The system comprising a plurality of solar panels for absorbing solar energy and converting the absorbed solar energy into electric energy, a charging controller to monitor the charging process of the battery pack using the solar panels, a solar irradiance sensor positioned on the solar panels to measure real-time sunlight intensity, a battery State of Charge (SoC) sensor located on the battery pack to monitor the power level of the battery pack.

In another aspect of the present invention, when the SoC sensor detects the power level exceeding a predefined threshold, the electrical energy from the solar panels is directed to power HVAC and other electrical components of the electric vehicle. When the SoC sensor detects the power level falling below the threshold, the electrical energy from the solar panels is directed to charge the battery pack.

In yet another embodiment, the system includes a memory which is adapted to store historical energy usage patterns and weather data, optionally coupled with the GPS unit of the electric vehicle, enabling route-based optimization of the solar panel system's energy allocation.

Numerous benefits and advantages of this invention will become apparent to those skilled in the art to which it pertains upon reading and understanding of the following detailed specification.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and are intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a perspective view of one potential embodiment of the solar panels equipped electric vehicle of the present invention in accordance with the disclosed structure;

FIG. 2 illustrates a perspective view of the specialized device of the present invention designed to increase the battery range of electrically powered automobiles in accordance with the disclosed structure; and

FIG. 3 illustrates a functional block diagram showing connection of the solar panels of the solar charging system of the present invention for charging the electric battery pack of the vehicle in accordance with the disclosed structure.

### DETAILED DESCRIPTION OF THE PRESENT INVENTION

The innovation is now described with reference to the drawings, wherein like reference numerals are used to refer to like elements throughout. In the following description, for purposes of explanation, numerous specific details are set forth in order to provide a thorough understanding thereof. It may be evident, however, that the innovation can be practiced without these specific details. In other instances, well-known structures and devices are shown in block diagram form in order to facilitate a description thereof. Various embodiments are discussed hereinafter. It should be noted that the figures are described only to facilitate the description of the embodiments. They are not intended as an exhaustive description of the invention and do not limit the scope of the invention. Additionally, an illustrated embodiment need not have all the aspects or advantages shown. Thus, in other embodiments, any of the features described herein from different embodiments may be combined.

As noted above, there is a long felt need in the art for an alternative system for charging batteries of an electric vehicle. Additionally, there is a long felt need in the art for an electric vehicle that enables vehicle passengers to travel longer amounts of time and to travel longer distances without requiring frequent charges. Moreover, there is a long felt need in the art for a novel solar charging system for EV owners that can be affixed directly to the roof area of the vehicle. Further, there is a long felt need in the art for an EV solar charging system that can be installed on a roof of a vehicle to recharge vehicular battery to prevent users from running out of battery power. Furthermore, there is a long felt need in the art for a solar charging system that is durable and that makes it easier for individuals to buy electric vehicles by reducing charging problems of electric vehicles. Finally, there is a long felt need in the art for a solar charging system and method for electric vehicles that reduce frequent charging requirements of the EVs and reliance upon charging stations.

The present invention, in one exemplary embodiment, is a multi-layered solar charging device for installation on the roof of an electric vehicle. The device includes a top or outer layer constructed from transparent and toughened glass. The top or outer layer provides both visibility and protection against environmental elements, including rain, wind, and debris. A middle layer which includes a plurality of integrated solar panels. Each solar panel is designed to absorb solar energy and convert it into electric power. A bottom or inner layer constructed from either transparent or tinted glass. The bottom or inner layer serves as an additional protective barrier and an insulation layer for the interior of the electric vehicle. The device is designed to adapt to the design and structure of various electric vehicles, whether integrated during the manufacturing process of an electric vehicle, or as a retrofit aftermarket product, enhancing the vehicle's energy efficiency.

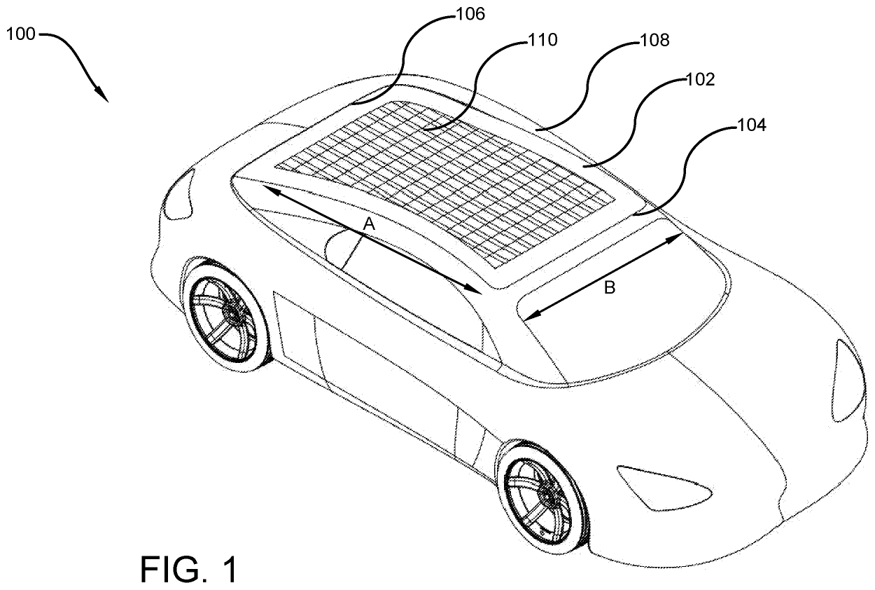

Referring initially to the drawings, FIG. 1 illustrates a perspective view of one potential embodiment of the solar panels equipped electric vehicle of the present invention in accordance with the disclosed structure. The electric vehicle 100 equipped with solar panels is designed to charge built-in vehicular batteries using solar panels to enable vehicle owners to travel longer distances without requiring frequent charges. More specifically, the solar panels equipped electric vehicle 100 includes a panoramic roof 102 that extends between a front end 104 and a rear end 106 of the roof 102. A top surface or outer layer 108 of the solar panels is integrated into the electric vehicle 100. The panoramic roof 102 is preferably transparent or semi-transparent and is designed to provide passengers with an expansive view of the surroundings while providing ample natural light.

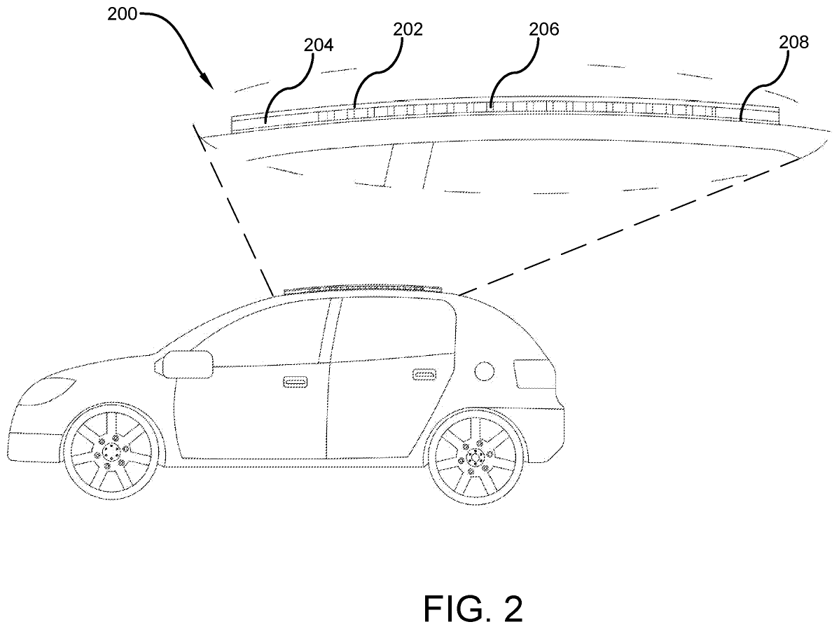

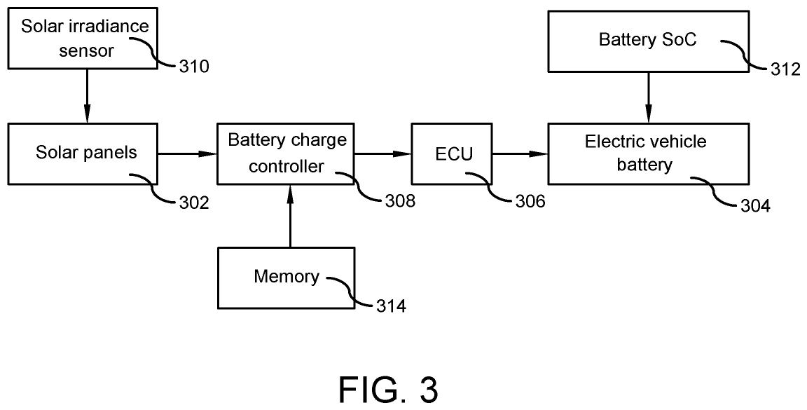

A plurality of solar panels 110 are integrated into the panoramic roof 102 for absorbing solar energy and converting the absorbed solar energy into electric energy for recharging the vehicle's battery pack (as illustrated in FIG. 3). Preferably, the solar panels 110 extend along at least 90% of the length (Arrow A) of the roof 102 and along at least 90% of the width (Arrow B) of the roof 102 to cover at least 80% of the area of the roof 102. The solar panels 110 are covered by a clear toughened glass layer as described in FIG. 2 for protection from weather elements and physical damage. The solar panels 110 are designed to match the curvature or shape of the vehicle's roof 102 to minimize any potential disruption to the view. Preferably, the solar panels 110 are made of thin-film solar cell or solar glass to enable natural light to pass therethrough.

FIG. 2 illustrates a perspective view of the specialized device of the present invention designed to increase the battery range of electrically powered automobiles in accordance with the disclosed structure. The solar charging vehicle roof device 200 can be integrated into an electric vehicle as described in FIG. 1 or can be used as an aftermarket product to install in existing electric vehicles. The multi-layered solar charging device 200 is installed on the roof of an EV and is preferably transparent or semi-transparent. The device 200 is designed to meet the design and structure of different electric vehicles. The solar charging vehicle roof device 200 includes a top or outer layer 202 made of transparent or semi-transparent and toughened glass from 1 mm to 4 mm in thickness. The top or outer layer 202 provides visibility and protection against environmental elements like rain, wind, and debris.

A middle layer 204 includes solar panels 206. The solar panels 206 are made of thin-film solar cell or solar glass to enable natural light to pass therethrough. The solar panels 206 are integrated directly into the middle layer 204 to collect solar energy and convert it into electric power. Necessary wiring to connect the solar panels 206 with the electric battery of an electric vehicle is also positioned in the middle layer 204. The middle layer 204 is thicker than the top or outer layer 202 and may have a thickness in the range from about 3 mm to about 8 mm. A bottom or inner layer 208 may be made from transparent, semi-transparent, or tinted glass. The inner layer 208 is also configured to provide additional protective barrier and insulation for the vehicle's interior.

FIG. 3 illustrates a functional block diagram showing connection of the solar panels of the solar charging system of the present invention for charging the electric battery pack of the vehicle in accordance with the disclosed structure. The solar panels 302 are connected to the internal battery 304 of the vehicle using the ECU 306 of the vehicle. The solar panels 302 are made of quantum-dot enhancements to ensure optimal light absorption, even in non-optimal lighting conditions. Furthermore, advanced semiconductor materials having engineered bandgap properties to amplify conversion efficiency of the solar cells are used for making the solar panels 302. A charging controller 308 monitors the charging process of the battery 304 using the solar panels 302.

A solar irradiance sensor 310 is disposed on the solar panels 302 and is adapted to measure the intensity of sunlight falling on the solar panels 302 in real-time. If the sunlight intensity is less than a threshold, then the connection of the solar panels 302 is automatically disconnected from the battery 304 by the charging controller 308. A battery state of charge (SoC) sensor 312 is disposed on the battery 304 and is adapted to monitor the battery power level of the battery 304. In cases, when the battery SoC 312 detects the power level above a power threshold, the electrical energy from the solar panels 302 is directed to power HVAC and other electrical components of the electric vehicle. If the battery SoC 312 detects the power level less than the power threshold, then the electrical energy from the solar panels 302 is directed to the battery pack 304.

A memory 314 is adapted to store historical energy usage patterns and weather data of the planned route of the electric vehicle. In some embodiments, the system 200 can be coupled to the GPS unit (not shown) of the electric vehicle to trace the planned route.

In one embodiment, the charging controller 308 receives the weather data of a route from the memory 314. In situations where the weather data indicates the weather to be cloudy or gloomy, then, the solar panels are used for providing electrical energy for HVAC and other electronic functions of the vehicle and not the battery pack charging as the power level is less than the threshold.

Certain terms are used throughout the following description and claims to refer to particular features or components. As one skilled in the art will appreciate, different persons may refer to the same feature or component by different names. This document does not intend to distinguish between components or features that differ in name but not structure or function. As used herein “solar panels equipped electric vehicle”, “solar panels integrated electric vehicle”, “electric vehicle”, and “vehicle” are interchangeable and refer to the solar panels equipped electric vehicle 100 of the present invention. Similarly, as used herein, “solar charging vehicle roof device”, “multi-layered solar charging device”, and “solar charging system” are interchangeable and refer to the vehicular multi-layered solar charging device 200 of the present invention.

Notwithstanding the forgoing, the solar panels equipped electric vehicle 100 and vehicular multi-layered solar charging device 200 of the present invention can be of any suitable size and configuration as is known in the art without affecting the overall concept of the invention, provided that they accomplish the above stated objectives. One of ordinary skill in the art will appreciate that the solar panels equipped electric vehicle 100 and vehicular multi-layered solar charging device 200 as shown in the FIGS. are for illustrative purposes only, and that many other sizes and shapes of the solar panels equipped electric vehicle 100 and vehicular multi-layered solar charging device 200 are well within the scope of the present disclosure. Although the dimensions of the solar panels equipped electric vehicle 100 and vehicular multi-layered solar charging device 200 are important design parameters for user convenience, the solar panels equipped electric vehicle 100 and vehicular multi-layered solar charging device 200 may be of any size that ensures optimal performance during use and/or that suits the user's needs and/or preferences.

Various modifications and additions can be made to the exemplary embodiments discussed without departing from the scope of the present invention. While the embodiments described above refer to particular features, the scope of this invention also includes embodiments having different combinations of features and embodiments that do not include all of the described features. Accordingly, the scope of the present invention is intended to embrace all such alternatives, modifications, and variations as fall within the scope of the claims, together with all equivalents thereof.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. An electric vehicle equipped with solar panels comprising:
an electric vehicle;
a solar panel; and
a vehicle roof;
wherein said vehicle roof is a panoramic roof extending from a front end to a rear end having an outer layer, a middle layer, and an inner layer;
wherein said middle layer is said solar panel for absorbing solar energy and converting said solar energy into electric energy; and
further wherein said solar panel connected to said electric vehicle's built-in vehicular batteries for selectively charging said vehicular batteries.

2. The electric vehicle equipped with solar panels of claim 1, wherein said solar panel extends along at least 90% of a length of said vehicle roof and along at least 90% of a width of said vehicle roof.

3. The electric vehicle equipped with solar panels of claim 2, wherein said solar panel covers at least 80% of an area of said vehicle roof.

4. The electric vehicle equipped with solar panels of claim 3, wherein said solar panel having a material selected from the group consisting of a thin-film solar cell and a solar glass.

5. The electric vehicle equipped with solar panels of claim 3, wherein said outer layer is transparent glass.

6. The electric vehicle equipped with solar panels of claim 3, wherein said outer layer is semi-transparent glass.

7. The electric vehicle equipped with solar panels of claim 6, wherein said outer layer having a thickness from 1 mm to 4 mm.

8. The electric vehicle equipped with solar panels of claim 7, wherein said middle layer having a thickness from 3 mm to 8 mm.

9. An electric vehicle equipped with solar panels comprising:
an electric vehicle;
a solar panel; and
a vehicle roof;
wherein said vehicle roof is a panoramic roof extending from a front end to a rear end having an outer layer, a middle layer, and an inner layer;
wherein said middle layer is said solar panel for absorbing solar energy and converting said solar energy into electric energy;
wherein said solar panel connected to said electric vehicle's built-in vehicular batteries for selectively charging said vehicular batteries;
wherein said solar panel covers at least 80% of an area of said vehicle roof; and
further wherein said solar panel having a material selected from the group consisting of a thin-film solar cell and a solar glass.

10. The electric vehicle equipped with solar panels of claim 9, wherein said solar panel extends along at least 90% of a length of said vehicle roof and along at least 90% of a width of said vehicle roof.

11. The electric vehicle equipped with solar panels of claim 10, wherein said outer layer is transparent glass.

12. The electric vehicle equipped with solar panels of claim 10, wherein said outer layer is semi-transparent glass.

13. The electric vehicle equipped with solar panels of claim 12, wherein said outer layer having a thickness from 1 mm to 4 mm.

14. The electric vehicle equipped with solar panels of claim 13, wherein said middle layer having a thickness from 3 mm to 8 mm.

15. A method for charging built-in vehicular batteries of an electric vehicle, the method comprising the steps of:
providing an electric vehicle having an internal battery with a transparent vehicle roof, a solar panel, an ECU, a charging controller, and a solar irradiance sensor, wherein said vehicle roof is a panoramic roof extending from a front end to a rear end having an outer layer, a middle layer, and an inner layer, wherein said middle layer is said solar panel for absorbing solar energy and converting said solar energy into electric energy, further wherein said solar panel connected to said electric vehicle's built-in vehicular batteries for selectively charging said vehicular batteries;
wherein said solar irradiance sensor disposed on said solar panel adapted to measure an intensity of sunlight falling on said solar panel in real-time;
connecting said solar panel to said internal battery through said ECU; and
comparing said intensity of sunlight to a threshold intensity, wherein if said intensity of sunlight is less than said threshold intensity, disconnecting said solar panel from said internal battery by said charging controller.

16. The method for charging built-in vehicular batteries of claim 15, wherein said solar panel having quantum-dot enhancements for light absorption.

17. The method for charging built-in vehicular batteries of claim 15, wherein said charging controller monitoring a charging process of said internal battery from said solar panel.

18. The method for charging built-in vehicular batteries of claim 17 further comprising the steps of:
monitoring a battery power level of said internal battery with a battery SoC;
comparing said battery power level to a battery power threshold with said battery SoC; and
directing said electric energy to power electrical components of said electric vehicle when said battery power level is above said battery power threshold.

19. The method for charging built-in vehicular batteries of claim 18 further comprising a step of directing said electric energy to said internal battery of said electric vehicle when said battery power level is below said battery power threshold.

20. The method for charging built-in vehicular batteries of claim 19, wherein said solar panel covers at least 80% of an area of said vehicle roof;
wherein said solar panel having a material selected from the group consisting of a thin-film solar cell and a solar glass; and
further wherein said outer layer is transparent glass.
